(19) United States
(12) Patent Application Publication
(10) Pub. No.: US 2022/0397946 A1
(43) Pub. Date: Dec. 15, 2022

(54) VENTILATION SYSTEMS WITH SLIDABLE SYSTEM MESHES

(71) Applicant: Hewlett-Packard Development Company, L.P., Spring, TX (US)

(72) Inventors: Chin-Chang Ho, Taipei City (TW); Hung-Ming Lin, Taipei City (TW); Lan-Chin Chiou, Taipei City (TW); Wei-Chih Tsao, Taipei City (TW); Che-An Yao, Taipei City (TW)

(73) Assignee: Hewlett-Packard Development Company, L.P., Spring, TX (US)

(21) Appl. No.: 17/770,072

(22) PCT Filed: Oct. 31, 2019
(86) PCT No.: PCT/US2019/058998

§ 371 Date: Apr. 19, 2022

(51) Int. Cl. G06F 1/20; H05K 7/20; H05K 5/02

(52) U.S. Cl. CPC G06F 1/20; H05K 7/2039; H05K 5/0213

(57) ABSTRACT

An example ventilation system for a computing device includes: a cover slidably engageable with a housing of the computing device to a closed position defining an internal space of the computing device, the cover having first ventilation holes; a system mesh slidably engaged with the cover, the system mesh having second ventilation holes; and a stopper disposed in the internal space of the computing device, the stopper to stop the system mesh at a predefined position when the cover is engaged with the housing in the closed position, wherein the first ventilation holes and the second ventilation holes overlap to define system ventilation holes for the computing device.

### BACKGROUND

Computing devices generate heat and may include ventilation systems, including ventilation holes, to dissipate heat generated by components of the computing device.

### BRIEF DESCRIPTION OF THE DRAWINGS

FIG. 1A is an exploded view of an example computing device including an example ventilation system with a slidable system mesh.

FIG. 1B is a schematic diagram of a top view of the computing device of FIG. 1A.

FIG. 2A is a bottom view of an example ventilation system with a slidable system mesh to engage a stopper.

FIG. 2B is a bottom view of an example ventilation system with a slidable system mesh with a slot to receive a stopper.

FIG. 2C is a bottom view of an example ventilation system with a slidable system mesh with an extension to engage a stopper.

FIG. 3 is an exploded view of another example computing device including an example ventilation system with a slidable system mesh.

FIG. 4A is a partial view of an example ventilation system with partially overlapping ventilation holes.

FIG. 4B is a partial view of an example ventilation system with fully overlapping ventilation holes.

FIG. 4C is a partial view of an example ventilation system with ventilation holes having different spatial arrangements.

FIG. 5 depicts a flowchart of an example method of adjusting system ventilation holes.

### DETAILED DESCRIPTION

Computing devices, such as personal computers, laptops, desktops, or other types of computing devices such as imaging devices and the like, may be built for different types of operations. Different computing devices with different system components generate different amounts of heat, and accordingly utilize different ventilation systems.

Some ventilation systems include fixed grills or vents to allow air to flow to the internal space of computing devices. The fixed grills do not accommodate a range of different computing devices which produce different amounts of heat and may benefit from additional ventilation to dissipate heat, or less ventilation to reduce noise and dust clogging the internal components. Some ventilation systems include movable boards on a base so that openings on the moveable board partially overlap with corresponding openings on the base to give various flow resistances. The moveable board may be positioned using a positioning part aligned in positioning holes to secure the moveable board. The moveable board is manually positioned and secured and does not cooperate with the base based on the internal components to align the moveable board for different flow resistances.

An example ventilation system for a computing device includes a cover having first ventilation holes and a system mesh having second ventilation holes. The system mesh is slidably engaged with the cover to allow for variable size system ventilation holes defined by the overlap between the first ventilation holes and the second ventilation holes. The cover is slidably engageable with a housing of the computing device to a closed position, wherein, when the cover is in the closed position, an internal space of the computing device is defined between the cover and the housing. The ventilation system further includes a stopper in the internal space of the computing device to stop the system mesh at a predefined position to define the system ventilation holes. Thus, different computing devices may have stoppers to stop the system mesh in different predefined positions to allow for variability and customization of the sizes of the system ventilation holes. For example, the first and second ventilation holes may fully overlap for larger system ventilation holes, or they may partially overlap for smaller ventilation holes. Thus, each computing device may be customized according to its optimal ventilation, in which heat is dissipated through the ventilation holes while minimizing the size of the ventilation holes to reduce noise (e.g., produced by the system fan) and to filter dust particles.

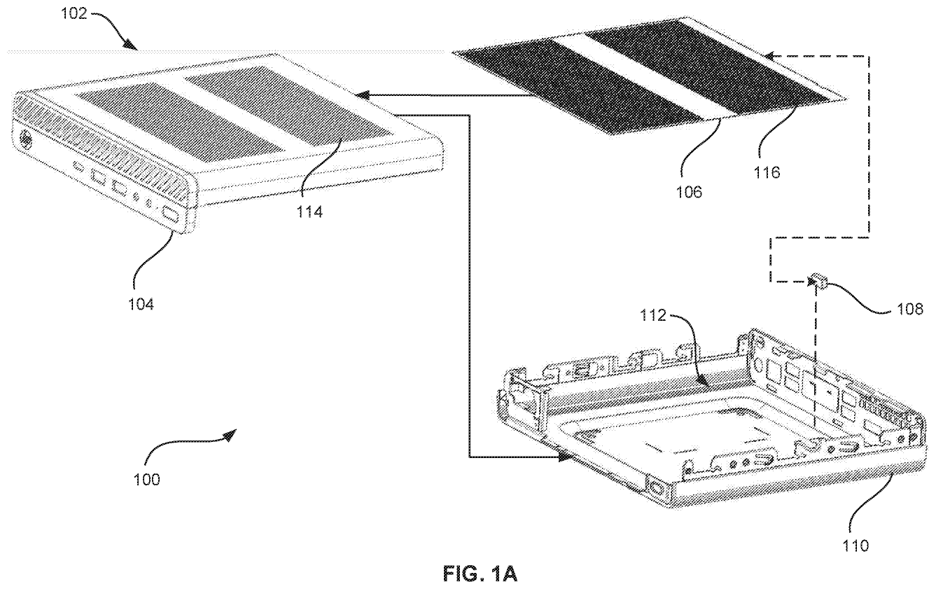

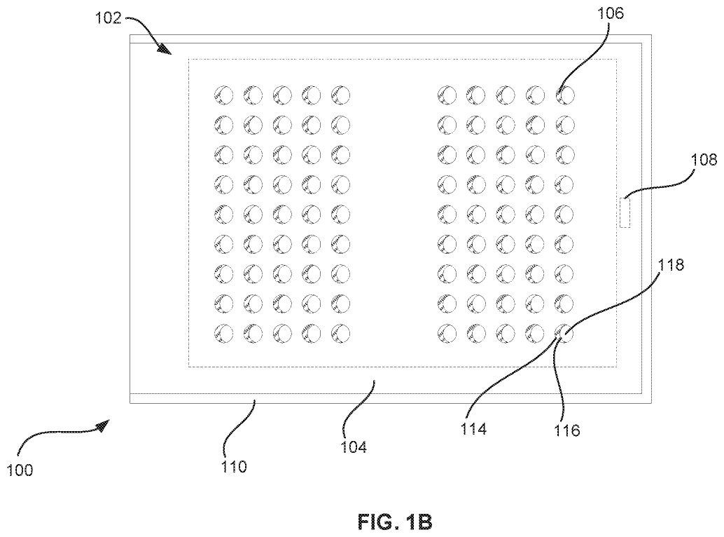

FIG. 1A shows a schematic diagram of an example computing device 100 including an example ventilation system 102. The computing device 100 includes a cover 104, a system mesh 106, a stopper 108, and a housing 110. Together, the cover 104, the system mesh 106, and the stopper 108 cooperate to form the ventilation system 102.

The cover 104 is to engage with the housing 110 of the computing device. Specifically, the cover 104 is slidably engageable with the housing 110 to a closed position, defining an internal space 112 of the computing device 100. The cover 104 further includes first ventilation holes 114. The first ventilation holes 114 may be apertures, windows, or other openings in the cover 104 that extend through a thickness of the cover 104. Together, the first ventilation holes 114 define a grill or a vent in the cover that may allow the passage of air through the cover 104.

The system mesh 106 is slidably engaged with the cover 104 and includes second ventilation holes 116. The second ventilation holes 116 may be apertures, windows, or other openings in the system mesh 116 that extend through a thickness of the cover 106. Together, the second ventilation holes 116 define a grill or a vent in the system mesh 106 that may allow the passage of air through the system mesh 106.

The stopper 108 is disposed in the internal space 112 of the computing device 100. The stopper 108 is to stop the system mesh 106 at a predefined position when the cover 104 is engaged with the housing 110 in the closed position. That is, as the cover 104 slides towards the closed position on the housing 110, the stopper 108 engages the system mesh 106 and stops it from sliding further, even as the cover 104 continues to slide towards the closed position.

For example, referring to FIG. 1B, a top view of the ventilation system 102 of the computing device 100 is depicted, when the cover 104 is engaged with the housing 110 in the closed position. When the cover 104 is in the closed position, the first ventilation holes 114 of the cover 104 and the second ventilation holes 116 of the system mesh 106 overlap to define system ventilation holes 118. In the present example, the stopper 108 stops the system mesh 106 in a position where the first ventilation holes 114 and the second ventilation holes 116 partially overlap.

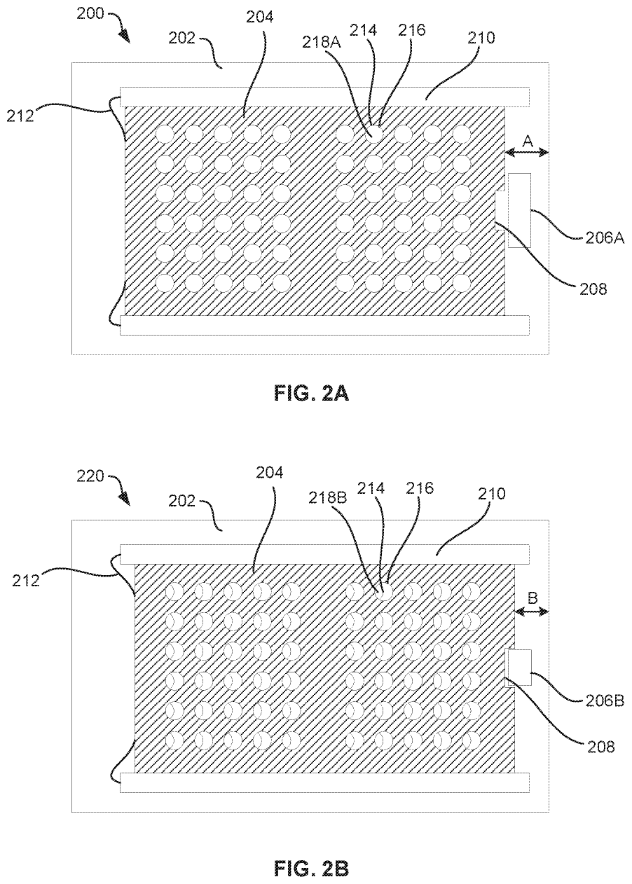

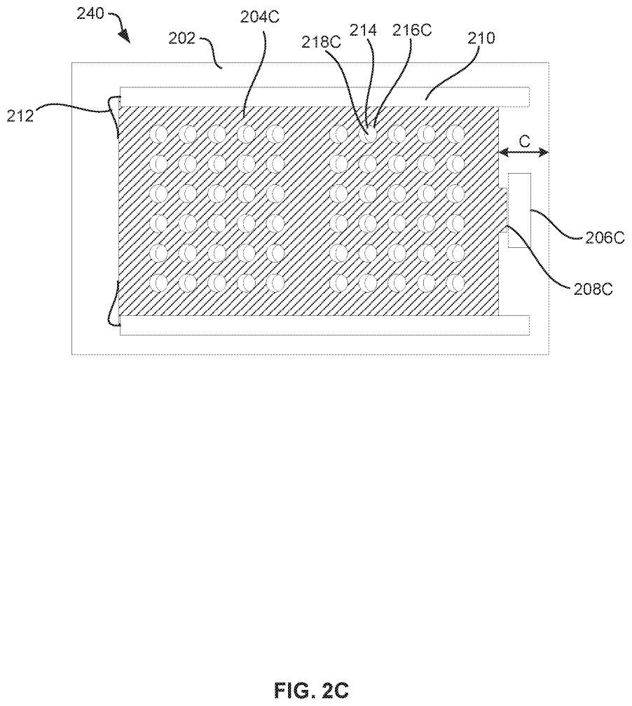

FIG. 2A depicts a schematic of a bottom view of an example ventilation system 200 including a cover 202, a system mesh 204 and a stopper 206A. The ventilation system 200 further includes rails 210 and a spring 212.

The cover 202 and the system mesh 204 are similar to the cover 104 and the system mesh 106, respectively. In particular, the cover 202 includes first ventilation holes 214 and is slidably engageable with a housing of a computing device (not shown). The system mesh 204 is slidably engaged with the cover 202 and includes second ventilation holes 216. The first ventilation holes 214 and the second ventilation holes 216 overlap to form system ventilation holes 218A. The system mesh 204 further includes a slot 208.

The rails 210 are connected to the cover 202 to guide the system mesh 204 as the system mesh 204 slides along the cover 202. In particular, the rails 210 may reduce lateral movement of the system mesh 204 as it slides along the cover 202 to keep the second ventilation holes 216 laterally aligned with the first ventilation holes 214.

The spring 212 is disposed at an end of the rails 210, and, more particularly, at the end of the rails 210 distal from the stopper 206A. The spring 212 is a biasing member capable of undergoing elastic deformation. In particular, the spring 212 engages the system mesh 204 when the system mesh 204 is stopped in its predefined position with respect to the cover 202. The system mesh 204 thus causes an elastic deformation of the spring 212. In response to the elastic deformation, the spring 212 exerts a reactionary force against the system mesh 204 to bias the system mesh 204 against the stopper 206A.

In the present example, the cover 202 is in the closed position with respect to the housing of the computing device. Accordingly, the stopper 206A is engaged with the system mesh 204 to stop the system mesh 204 in a predefined position with respect to the cover 202. For example, the system mesh 204 may be stopped a distance A away from an end of the cover 202. In particular, the stopper 206A is wider than the slot 208, and accordingly cannot be received within the slot 208. Rather, the stopper 206A engages with an end of the system mesh 204 adjacent the slot 208. Further, the spring 212 keeps the system mesh 204 in the predefined position relative to the cover 202 by biasing the system mesh 204 against the stopper 206A. That is, the spring 212 prevents the system mesh 204 from sliding away from the stopper 206A.

In said closed position, the ventilation holes 214 and 216 of the cover 202 and the system mesh 204 overlap to form the system ventilation holes 218A. For example, when the system mesh 204 is the distance A away from the end of the cover 202, the respective ventilation holes 214 and 216 of the cover 202 and the system mesh 204 may fully overlap to define the system ventilation holes 218A.

FIG. 2B depicts a schematic bottom view of a ventilation system 220 including the cover 202, the system mesh 204 and a stopper 206B. The cover 202 is similarly in the closed position with respect to the housing of the computing device (not shown). Accordingly, the stopper 206B is engaged with the system mesh 204 to stop the system mesh 204 in a different predefined position with respect to the cover 202. In particular, the stopper 206B is shaped to be received in the slot 208. The system mesh 204 is therefore able to slide further towards the end of the cover 202 as the stopper 206B is received in the slot 208. Thus, when the stopper 206B is received in the slot 208, the system mesh 204 may be stopped a distance B away from an end of the cover 202.

Further, the ventilation system 220 may include the rails 210 and the spring 212. The rails 210 guide the system mesh 204 as the system mesh 204 slides along the cover 202. In particular, the rails 210 reduce lateral movement of the system mesh 204 to allow the stopper 206B to be received in the slot 208. Further, the spring 212 biases the system mesh 204 against the stopper 206B. In particular, the spring 212 maintains the stopper 206B in the slot 208 of the system mesh 204.

In said closed position, the ventilation holes 214 and 216 of the cover 202 and the system mesh 204 overlap to form system ventilation holes 218B. For example, when the system mesh 204 is the distance B away from the end of the cover 202, the respective ventilation holes 214 and 216 of the cover 202 and the system mesh 204 may partially overlap to define the system ventilation holes 218B.

Thus, the system ventilation holes 218A may allow greater air flow relative to the system ventilation holes 218B. A computer device having higher heat dissipation conditions may thus employ the stopper 206A to stop the system mesh 204 at the distance A to allow for full overlap of the ventilation holes 214 and 216, and hence, larger system ventilation holes 218A. In contrast, a computing device having lower heat dissipation conditions may employ the stopper 206B to stop the system mesh 204 at the distance B to produce a partial overlap of the ventilation holes 214 and 216, and hence, smaller system ventilation holes 218B.

FIG. 2C depicts a schematic bottom view of a ventilation system 240 including the cover 202, a system mesh 2040, and a stopper 2060. The cover 202 is similarly in the closed position with respect to the housing of the computing device (not shown). Accordingly, the stopper 2060 is engaged with the system mesh 2040 to stop the system mesh 2040 in yet another different predefined position with respect to the cover 202. In particular, the system mesh 2040 includes an extension 2080 rather than the slot 208. The extension 2080 engages the stopper 2060 rather than the end of the system mesh 2040 adjacent to the extension 208C. Thus, when the extension 208C engages the stopper 2060, the system mesh 204C may be stopped a distance B away from an end of the cover 202.

As with the ventilation systems 200 and 240, the rails 210 guide the system mesh 204C as the system mesh 2040 slides along the cover 202. In particular, the rails 210 reduce lateral movement of the system mesh 2040. Further, the spring 212 biases the system mesh 2040 against the stopper 206C. In particular, the spring 212 maintains engagement of the extension 208C with the stopper 2060.

In said closed position, the ventilation holes 214 of the cover and ventilation holes 2160 of the system mesh 2040 overlap to form system ventilation holes 2180. For example, when the system mesh 2040 is the distance C away from the end of the cover 202, the ventilation holes partially overlap to define the system ventilation holes 2180.

Thus, the system ventilation holes 2180 may allow relatively less airflow than the system ventilation holes 218A, but more airflow than the system ventilation holes 218B.

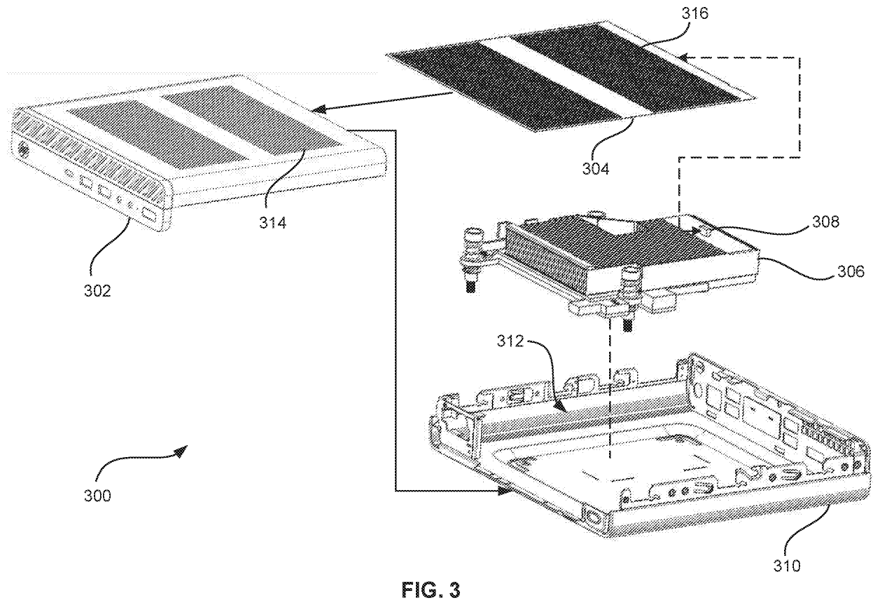

FIG. 3 depicts a schematic diagram of another example computing device 300. The computing device 300 includes a cover 302, a system mesh 304, a heat sink 306 including a stopper 308, and a housing 310.

The cover 302, the system mesh 304, and the stopper 308 are similar to the cover 104, the system mesh 106 and the stopper 108, respectively. Specifically, the cover 302 is slidably engageable with the housing 310 to a closed position, defining an internal space 312 of the computing device 300. The cover 302 further includes first ventilation holes 314. The system mesh 304 is slidably engaged with the cover 302 and includes second ventilation holes 316. The first ventilation holes 314 and the second ventilation holes 316 overlap to form system ventilation holes.

The heat sink 306 is disposed in the internal space 312 of the computing device 300 and is to absorb heat generated by internal components of the computing device 300. Specifically, the heat sink 306 may be selected based on heat dissipation conditions of the computing device 300. For example, a computing device including a high-power graphics card may typically generate more heat than a computing device including a low-power or no graphics card. Accordingly, the two computing devices may have different heat dissipation conditions, and may therefore include different heat sinks. Each computing device may also have a different optimal ventilation, according to heat dissipation conditions, system noise, and dust filtration. In particular, the optimal ventilation may minimize the size of the ventilation holes to reduce system noise and to filter dust particles to reduce dust clogging, while providing sufficient ventilation according to the heat dissipation conditions.

The heat sink 306 further includes the stopper 308 disposed thereon. In particular, the stopper 308 is disposed on the heat sink 306 to stop the system mesh 304 to adjust the system ventilation holes based on an optimal ventilation for heat dissipation for the computing device 300. In particular, the stopper 308 may stop the system mesh 304 at a predefined position when the cover 302 is engaged with the housing 310 in the closed position. That is, as the cover 302 slides towards the closed position on the housing 310, the stopper 308 engages the system mesh 304 and stops it from sliding further, even as the cover 302 continues to slide towards the closed position.

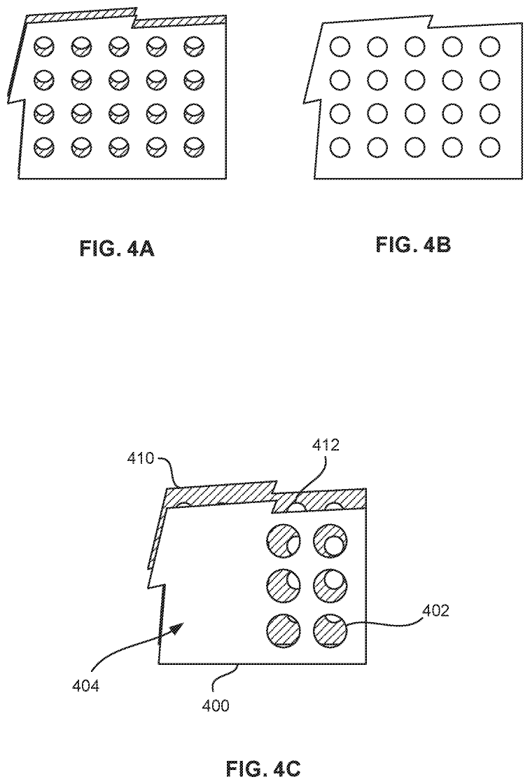

For example, the stopper 308 may stop the system mesh 304 in a predefined position resulting in a partial overlap of the first ventilation holes 314 and the second ventilation holes 316 to adjust the system ventilation holes to have a partial opening rate for a computing device having a lower optimal ventilation. That is, the first ventilation holes 314 may be partially blocked by the system mesh 304, as depicted in FIG. 4A.

Similarly, the stopper 308 may stop the system mesh 304 in a different predefined position resulting in a full overlap of the first ventilation holes 314 and the second ventilation holes 316 to adjust the system ventilation holes to have a full opening rate for a computing device having a higher optimal ventilation. That is, the first ventilation holes 314 are not blocked by the system mesh 304, as depicted in FIG. 4B.

In other examples, the stopper 308 may be disposed on the housing 310 of the computing device 300, or on other internal components of the computing device 300.

In the examples depicted in FIGS. 4A and 4B, the first ventilation holes 314 and the second ventilation holes 316 are in direct spatial correspondence. In other examples, for example as depicted in FIG. 4C, the ventilation holes may have different spatial arrangements. For example, a cover 400 may have first ventilation holes 402 in a first spatial arrangement, while the system mesh 410 may have second ventilation holes 412 in a second spatial arrangement. In particular, the first spatial arrangement of the cover 400 may include larger first ventilation holes 402, as well as a blocked area 404, which contains no ventilation holes. The system mesh 410 may have relatively smaller ventilation holes 412. Thus, the system ventilation holes defined by the overlap of the first ventilation holes 402 and the second ventilation holes 412 may be further customized according to heat dissipation conditions and optimal ventilation for the computing system.

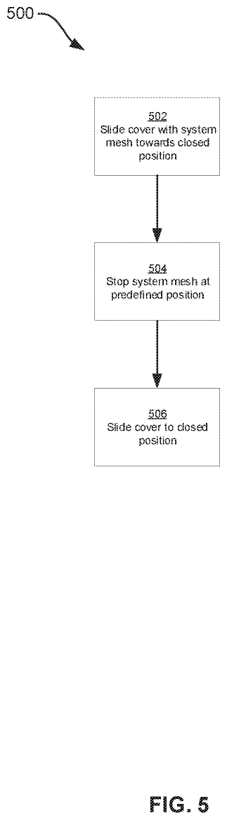

Referring to FIG. 5, a flowchart of a method 500 of adjusting system ventilation holes of a computing device is depicted.

At block 502, a cover is slid onto a housing of the computing device towards a closed position. In particular, the cover is slid with a system mesh, wherein the system mesh is slidably engaged with the cover.

At block 504, a stopper disposed in an internal space of the computing device stops the system mesh at a predefined position. In particular, the predefined position may be defined relative to the housing or the internal space of the computing device. In some examples, the system mesh may include a slot to receive the stopper. Accordingly, the stopper may stop the system mesh when it is received in the slot of the system mesh.

At block 506, the cover continues to slide until it reaches the closed position with respect to the housing of the computing device. In particular, as the system mesh is stopped from sliding further, the cover additionally slides relative to the system mesh. For example, the system mesh may slide along rails of the cover.

When the cover is in the closed position at block 506, and the system mesh is at the predefined position per block 504, first ventilation holes of the cover and second ventilation holes of the system mesh overlap to define the system ventilation holes.

In some examples, the cover may further include a spring to bias the system mesh against the stopper. Thus, the system mesh may be prevented from sliding away from the stopper and out of the predefined position.

In some examples, the method 500 may further include selecting a position of the stopper to adjust the system ventilation holes based on an optimal ventilation for heat dissipation for the computing device. For example, different heat sinks may have stoppers in different positions thereon to correspond to different opening rates of the system ventilation holes.

As described above, a ventilation system includes a cover having first ventilation holes and a system mesh having second ventilation holes which are slidably engaged to allow for variable size system ventilation holes defined by the overlap of the first and second ventilation holes. The ventilation system further includes a stopper to stop the system mesh at a predefined position based on heat dissipation conditions and optimal ventilation for the computing device. In particular, the stopper stops the system mesh to adjust opening rates of the system ventilation holes to control ventilation through the ventilation holes. Thus, different computing devices with different optimal ventilation may have stoppers in different positions to stop the system mesh in different predefined positions. The stopper may be placed on a heat sink of the computing device. Thus, different computing devices using different heat sinks may also select the position of the stopper based on the selection of the heat sink for the computing device.

The scope of the claims should not be limited by the above example but should be given the broadest interpretation consistent with the description as a whole.

1. A ventilation system for a computing device, the ventilation system comprising:
a cover slidably engageable with a housing of the computing device to a closed position defining an internal space of the computing device, the cover having first ventilation holes;
a system mesh slidably engaged with the cover, the system mesh having second ventilation holes; and
a stopper disposed in the internal space of the computing device, the stopper to stop the system mesh at a predefined position when the cover is engaged with the housing in the closed position, wherein the first ventilation holes and the second ventilation holes overlap to define system ventilation holes for the computing device.

2. The ventilation system of claim 1, wherein the stopper is disposed on a heat sink of the computing device.

3. The ventilation system of claim 1, wherein the system mesh comprises a slot to receive the stopper when the cover is engaged with the housing in the closed position.

4. The ventilation system of claim 1, wherein the system mesh comprises an extension to engage the stopper when the cover is engaged with the housing in the closed position.

5. The ventilation system of claim 1, wherein, at the predefined position, the first ventilation holes and the second ventilation holes fully overlap to define the system ventilation holes.

6. The ventilation system of claim 1, wherein, at the predefined position, the first ventilation holes and the second ventilation holes partially overlap to define the system ventilation holes.

7. The ventilation system of claim 1, further comprising a spring to bias the system mesh against the stopper.

8. The ventilation system of claim 1, wherein a first spatial arrangement of the first ventilation holes is different from a second spatial arrangement of the second ventilation holes.

9. A computing device comprising:
a housing;
a cover slidably engageable with the housing of the computing device to a closed position defining an internal space of the computing device, the cover having first ventilation holes;
a system mesh slidably engaged with the cover, the system mesh having second ventilation holes overlapping with the first ventilation holes to form system ventilation holes; and
a heat sink disposed in the internal space of the computing device to absorb heat generated by internal components of the computing device, the heat sink including a stopper disposed thereon; and
wherein the stopper is to stop the system mesh to adjust the system ventilation holes based on an optimal ventilation for heat dissipation for the computing device.

10. The computing device of claim 9, wherein the stopper is to stop the system mesh to adjust the system ventilation holes to have a partial opening rate.

11. The computing device of claim 9, wherein the stopper is to stop the system mesh to adjust the system ventilation holes to have a full opening rate.

12. A method of adjusting system ventilation holes of a computing device, the method comprising:
sliding a cover with a system mesh of the computing device onto a housing of the computing device towards a closed position, the system mesh slidably engaged with the cover;
stopping, by a stopper disposed in an internal space of the computing device, the system mesh at a predefined position; and
sliding the cover to the closed position, wherein, when the cover is in the closed position and the system mesh is at the predefined position, first ventilation holes of the cover and second ventilation holes of the system mesh overlap to define the system ventilation holes.

13. The method of claim 12, wherein stopping the system mesh comprises receiving the stopper in a slot of the system mesh.

14. The method of claim 12, further comprising biasing the system mesh against the stopper.

15. The method of claim 12, further comprising selecting a position of the stopper to adjust the system ventilation holes based on an optimal ventilation for heat dissipation for the computing device.
